(19) United States
(12) Patent Application Publication
(10) Pub. No.: US 2014/0268552 A1
(43) Pub. Date: Sep. 18, 2014

(54) SERVER WITH HEAT BAFFLE COOLING

(71) Applicant: Silicon Graphics International Corp., Fremont, CA (US)

(72) Inventors: Ronald Provenzale, Fremont, CA (US); Seitu Barron, Newark, CA (US); Robert Michael Kinstle III, Livermore, CA (US); Kevin Schlichter, Livermore, CA (US)

(73) Assignee: Silicon Graphics International Corp., Fremont, CA (US)

(21) Appl. No.: 13/931,814

(22) Filed: Jun. 29, 2013

Related U.S. Application Data
(60) Provisional application No. 61/780,787, filed on Mar. 13, 2013.

(51) Int. Cl. H05K 7/20

(52) U.S. Cl. CPC H05K 7/20727; H05K 7/20145
USPC 361/679.51; 361/679.46

(57) ABSTRACT

A server provides for improved cooling using one or more baffles. The baffles allow for increased cooling efficiencies by directing heat in such a manner as to reduce heat exposure for temperature sensitive hardware and data center employees. The baffle may be disposed within a server and direct hot air through the server away from temperature sensitive devices. The baffle may include an inlet that receives hot air and an outlet through which hot air may exit. One or more fans may be used to direct air through the baffle. For example, the baffle may direct heat from the baffle inlet to the baffle outlet, directing heat away from temperature sensitive devices within the server.

### CROSS-REFERENCE TO RELATED APPLICATIONS

This application claims the priority benefit of U.S. Provisional Application Ser. No. 61/780,787, titled “SERVER WITH HEAT BAFFLE COOLING,” filed Mar. 13, 2013, the disclosure of which is incorporated herein by reference.

### BACKGROUND

1. Field of the Invention

The present invention relates to server cooling systems. More specifically, the present invention relates to cooling servers using heat baffle cooling.

2. Description of the Related Art

Servers are computers that manage access to centralized resources or services in a network. Data centers house several servers at the same time, often storing each server in a chassis, such as a tray or blade. Several trays are commonly stored in a single cabinet, and the cabinets are often arranged in rows separated by an aisle. Because servers generate heat that can damage temperature sensitive devices, the servers must be cooled.

Servers are commonly cooled by exhausting hot air from the server into one of the aisles. Each row of cabinets typically exhausts heat into the same aisle. The aisle receiving heat from the cabinets is known as “the hot aisle,” while the aisle on the opposite side of the cabinets is referred to as “the cold aisle.” Increased temperatures in the hot aisle result in better cooling efficiencies. Accordingly, it is advantageous to make the temperature in the hot aisle as high as possible. However, higher heats in the hot aisle can create greater health risks for data centers employees that must enter the aisle to, for example, manage cables, fix connection issues or perform routine maintenance or other tasks. The Occupational Safety and Health Administration (OSHA) enforces regulations that prevent data center employees from working in environments that are above a certain temperature.

Servers of the prior art have had the same layout for years, and lack the ability to be turned around so that their I/O terminals face into the cold aisle rather than the hot aisle (i.e., to allow data center employees to work in the cold aisle rather than the hot aisle). Connector limitations inherent in known motherboard designs require that the motherboard be located close to the I/O terminals. Accordingly, when a server of the prior art is simply turned around such that its I/O terminals face into the cold aisle, the motherboard must be located next to the cold aisle as well. This arrangement places the hard drive and other temperature sensitive devices downstream from the heat-generating motherboard. As a result, when air is blown into the server to exhaust the heat into the hot aisle, the hot air radiating from the motherboard is carried into contact with the hard drive. Such a configuration exposes the hard drive to dangerously high temperatures and can cause components to fail. There is a need in the art for a server with an improved cooling system that simultaneously allows for increased cooling efficiencies and reduces heat exposure for both sensitive hardware components and data center employees.

### SUMMARY

The server of the present invention provides for improved cooling using one of more baffles. The baffles allow for increased cooling efficiencies by directing heat in such a manner so as to reduce heat exposure for temperature sensitive hardware and data center employees. The baffle may be disposed within a server and direct hot air through the server away from temperature sensitive devices. The baffle may include an inlet that receives hot air and an outlet through which hot air may exit. One or more fans may be used to direct air through the baffle. The baffle, for example, may direct heat from the baffle inlet to the baffle outlet, directing heat away from temperature sensitive devices within the server.

In an embodiment, a server may include a tray that has a front end, a back end, a first side wall, and a second side wall. The first side wall may include a vent. The server may further include a temperature sensitive device. A first baffle may be disposed within the tray and have a first inlet and a first outlet. The baffle may direct hot air through first inlet and out the first outlet away from the temperature sensitive device.

### BRIEF DESCRIPTION OF DRAWINGS

FIG. 1 is a perspective view of an exemplary server having cooling baffles.

FIG. 2 is another perspective view of the exemplary server of FIG. 1.

FIG. 3 is a top view of two exemplary servers in a cabinet.

### DETAILED DESCRIPTION

A server with an improved cooling system is provided. The server of the present invention provides for improved cooling using one or more baffles. The baffles allow for increased cooling efficiencies by directing heat in such a manner so as to reduce heat exposure for temperature sensitive hardware and data center employees.

For purposes of this disclosure, the terms “tray,” “chassis,” “blade,” and “enclosure” may be utilized interchangeably to refer to a computer enclosure. The scope of the present invention may be applied to any enclosure-like system that includes temperatures sensitive components.

The server may manage access to centralized resources or services in a network. The server may be stored in a data center. Although data centers are discussed herein for illustrative purposes, the present technology may be useful for other entities as well. As described below in further detail, the present invention allows the hard drive and other temperature sensitive devices to be ventilated and cooled without exposure to dangerously hot air. The present invention does so by allowing server I/O terminals to face into the cold aisle and uses one or more heat baffles to divert the heat that radiates from the motherboard and the heat sink away from the downstream hard drive and other temperature sensitive devices. Because the I/O terminals face into the cold aisle, data center employees can work in the cold aisle rather than the hot aisle. As a result, the present invention reduces safety risks to employees and allows data centers to easily comply with OSHA regulations.

FIG. 1 shows an exemplary server having cooling baffles. The server may be arranged in a data center, for example, such that its I/O terminals face the cold aisle. A server 100 includes a tray 105 having a front end 110, a back end 120, a first side wall 130, and a second side wall 140. First side wall 130 includes a vent (see FIG. 2).

The server may also include a motherboard, a heat sink, a hard drive and several fans. The server motherboard (shown in FIG. 3) is disposed near a front end 110 of tray 105. The motherboard is coupled to the heat sink (also shown in FIG. 3), which dissipates heat from the motherboard. A hard drive 160 is disposed near a back end 120 of tray 105. Hard drive 160 is operatively connected to the motherboard and implements data storage for the server. A first fan 170 is disposed between hard drive 160 and the motherboard. A second fan 180 is disposed between hard drive 160 and front end 110 of tray 105. The first fan 170 and second fan 180 create an air flow within the server to cool the temperature of the server.

Server 100 may include an input/output (I/O) terminal 150 disposed in the front end 110 of tray 150. I/O terminal 150 may be operatively connected to the motherboard. Server 100 may further include a power supply 195 disposed in tray 105. Power supply 195 may be operatively connected to motherboard, first fan 170, second fan 180, and hard drive 160 to provide power to these elements.

A first baffle 185 may be disposed over the motherboard and the heat sink. First baffle 185 may include a first inlet 190, a first outlet 192, and a width 194. The first baffle may direct hot air which enters through the first inlet 190 and exits through the first outlet 192. First inlet 190 may be disposed against front end 110 of tray 105 and first outlet 192 may be disposed against first fan 170. First fan 170 may “pull” the hot air through the inlet and through the fan, thus creating a flow of hot air through the baffle.

First baffle 185 may substantially enclose the motherboard and the heat sink so that any heat radiated by the same is trapped within first baffle 185. Width 194 of first baffle 185 may be less than the distance between first wall 130 and second wall 140 of tray 105. Width 194 of first baffle 185 may define a first substantially unobstructed space bounded by front end 110, second side wall 140, second fan 180, and first baffle 185. First baffle 185 may be substantially rectangular, substantially triangular, or may have any shape that guides air out of the vent as shown in FIG. 3. First baffle 185 may be constructed from any material which may contain or direct a flow of hot air, such as plastic, composite, metal, or similar materials. First baffle 185 may be cast, pressed, or extruded according to commonly known manufacturing techniques.

The server tray arrangement shown in FIG. 1 may vary depending on various design considerations, including tray and cabinet dimensions, how much heat the motherboard and other components generate, and the materials selected. The arrangement may also vary depending on whether the tray is located on the left or right side of the cabinet. For example, the arrangement of a tray on the left side of a cabinet may constitute a mirror image of the arrangement of a tray on the right side of the cabinet.

FIG. 2 shows another perspective view of the exemplary server of FIG. 1. Server 200 may include a second baffle 230 disposed between hard drive 260 and first fan 270. Second baffle 230 may substantially enclose a second substantially unobstructed space and have a second inlet 240 and a second outlet 250. Second inlet 240 may be disposed against first fan 270, while second outlet 250 may be disposed against a vent 220 in first side wall 210. Second baffle 230 may include plastic or similar materials and may be cast, pressed, or extruded according to commonly known manufacturing techniques.

As noted above, multiple servers may be housed in a single cabinet. FIG. 3 is a top view of two exemplary servers housed in a cabinet 300. In operation, second fan 330 may draw cold air from the cold aisle into cabinet 300 at a front end location 310. The cold air may travel through a substantially unobstructed space 320 and pass through a second fan 330. Second fan 330 may direct the cold air over a hard drive 340. The air traveling over hard drive 340 is heated by the heat radiating from hard drive 340. Second fan 330 may act as an exhaust pump and push the heat out the back end of cabinet 300 and into the hot aisle. Doing so not only concentrates heat in the hot aisle, which increases cooling efficiencies, but also reduces the likelihood that hard drive 340 and any other heat-sensitive devices in the server will overheat and/or fail. In some embodiments, the power supply may include its own internal fan that draws air to create a beneficial cross stream over hard drive 340.

First fan 370 may draw cold air from the cold aisle into cabinet 300 at a front end location 350. The cold air may travel through the area enclosed by first baffle 360. In doing so, the cold air may cool motherboard 315 and heat sink 325 by drawing heat away from the same. First fan 370 may direct the heat into a substantially unobstructed area enclosed by a second baffle 390. Second baffle 390 may then exhaust the heat out of vent 380 into an unobstructed center channel 395 in cabinet 300. The exhausted heat may then be directed into the hot aisle by an additional fan (not shown). The additional fan may be disposed in the cold aisle, in the hot aisle, or within the center channel 395.

By exhausting the heat radiated by motherboard 315 and heat sink 325 into the center channel 395 and subsequently into the hot aisle, the present invention protects hard drive 340 and other temperature sensitive devices from failing. Because such components are effectively shielded from overheating, cabinet 300 can be arranged such that the I/O terminals of the servers face into the cold aisle. As a result, data center employees may service the cabinet while standing in the cold aisle rather than the hot aisle. Because the employees do not need to occupy the hot aisle, the data center may utilize the present invention to increase the temperature of the hot aisle without violating OSHA regulations. In doing so, the data center may also achieve increased cooling efficiencies.

For example, OSHA's maximum permissible wet-bulb globe temperature (WBGT) in the hot aisle is 86 degrees Fahrenheit when doing continuous work and 90 degrees Fahrenheit with a regimen of 25% work and 75% rest. Cooling efficiencies are highest when the hot aisle is maintained at over 100 degrees Fahrenheit. The present invention allows the hot aisle to remain over 100 degrees Fahrenheit while simultaneously allowing datacenter workers to work in the cold aisle—an environment within acceptable OSHA limits.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A server, comprising:
a tray having a front end, a back end, a first side wall, and a second side wall, the first side wall including a vent;
a temperature sensitive device; and
a first baffle disposed within the tray and having a first inlet and a first outlet, the baffle directing hot air through first inlet and out the first outlet and away from the temperature sensitive device.

2. The server of claim 1, further comprising:
a motherboard disposed near the front end of the tray, the motherboard coupled to a heat sink;
a hard drive disposed near the back end of the tray, the hard drive operatively connected to the motherboard;
a first fan disposed between the hard drive and the motherboard; and
a second fan disposed between the hard drive and front end of the tray, the first fan and the second fan directing the hot air through first inlet and out the first outlet.

3. The server of claim 2, wherein the first inlet is disposed against the front end of the tray and the first outlet is disposed against the first fan.

4. The server of claim 3, further comprising an input/output (I/O) terminal disposed in the front end of the tray and operatively connected to the motherboard.

5. The server of claim 3, wherein the first baffle substantially encloses the motherboard and the heat sink.

6. The server of claim 3, wherein the width of the first baffle is less than the distance between the first and second side walls of the tray.

7. The server of claim 6, wherein the width of the first baffle defines a first substantially unobstructed space bounded by the front end of the tray, the second side wall, the second fan, and the first baffle.

8. The server of claim 3, further comprising a second baffle disposed between the hard drive and the first fan, wherein the second baffle substantially encloses a second substantially unobstructed space and has a second inlet and a second outlet, wherein the second inlet is disposed against the first fan and the second outlet is disposed against the vent in the first side wall.

9. The server of claim 3, further comprising a power supply disposed in the tray, the power supply operatively connected to the motherboard, the first and second fans, and the hard drive.

10. The server of claim 3, wherein the shape of the first baffle is substantially rectangular.

11. The server of claim 8, wherein the shape of the second baffle is substantially triangular.

12. The server of claim 3, wherein the tray is installed in a rack having a plurality of trays, each tray having multiple hard drives for storing data.
